(19) United States
(12) Patent Application Publication
(10) Pub. No.: US 2026/0182430 A1
(43) Pub. Date: Jun. 25, 2026

(54) Method for the Manufacturing of a Hybrid Component and Associated Hybrid Component

(71) Applicant: LYNRED, Palaiseau (FR)

(72) Inventors: Pascal Le Boterf, Veurey-Voroize (FR); Lucas Duperrex, Veurey-Voroize (FR); Bastien Canas, Veurey-Voroize (FR)

(21) Appl. No.: 19/350,738

(22) Filed: Oct. 6, 2025

(30) Foreign Application Priority Data
Dec. 24, 2024 (FR) 2415212

(51) Int. Cl. H01L 23/00

(52) U.S. Cl. CPC H10W 72/073; H10W 72/072; H10W 72/07236; H10W 72/07304; H10W 72/07337; H10W 72/20; H10W 72/30; H10W 72/851; H10W 74/15; H10W 90/722; H10W 90/732

(57) ABSTRACT

A method of manufacturing a hybridized component includes attaching of a detection circuit to a readout circuit, and application of glue between the detection circuit and the readout circuit. The method also includes deposition of a sacrificial layer on the detection circuit before the step of attaching of the detection circuit to the readout circuit, so that the sacrificial layer extends at least over the edges of the detection circuit. The method further includes removal of the sacrificial layer after the step of application of the glue between the detection circuit and the readout circuit so as to form trenches around the detection circuit.

### TECHNICAL FIELD

The invention concerns a method of manufacturing a hybridized component as well as the associated hybridized component.

The invention has various applications, in particular in the fields of astronomy, of particle physics and of advanced detection technologies.

The invention has a particularly advantageous application for infrared detectors, and more specifically those operating at cryogenic temperatures.

### BACKGROUND

Hybridized components generally comprise a detection circuit mounted on a readout circuit with metal connections. Glue or resin is then conventionally applied between the detection circuit and the readout circuit to ensure the attaching of the two circuits and protect the metal connections.

However, the detection circuit, the readout circuit, and the glue conventionally have differences in thermal expansion coefficients. At cryogenic temperatures, these differences in thermal expansion coefficients can generate significant mechanical stress during the cooling and heating cycles. This mechanical stress appears in the form of tensile and compressive forces which act on the interfaces between materials.

Further, due to the wettability of the glue, the latter extends not only between the readout and detection circuits, but also on the sides of the detection circuit. This extension of the glue on the sides may exacerbate mechanical stress, thus increasing the tensile and compressive forces.

The forces efforts may cause cracks or delaminations, thus compromising the structural and functional integrity of the components. Risks for the components include:
cracking, where cracks may propagate through the interfaces, causing a mechanical failure;
delamination, which is the separation of the layers of materials, and which may cause a loss of electric contact and a degradation of the performance; and
thermal failure, which may occur when the cracks and the delaminations alter heat dissipation, causing a local overheating and additional failures.

In the sense of the invention, all these risks are gathered under the term cleavage.

To limit this risk of cleavage, it is known to use a stress-compensating substrate which compensates for the differences in thermal expansion coefficients between materials by absorbing and redistributing the mechanical stress. This stress-compensating substrate is generally formed from materials having thermomechanical properties adapted to minimize the deformations and tensions induced by temperature variations.

However, the addition of a stress-compensating substrate increases the total thickness of the assembly, which may pose problems of integration in systems where the space is limited. Further, the selection of the materials for the stress-compensating substrate needs to be carefully studied to ensure an optimal compatibility with the materials of the readout circuit, of the glue, and of the detection circuit, which limits available options.

Further, the integration of a stress-compensating substrate adds complexity to the manufacturing method, requiring more sophisticated gluing and assembly techniques. Finally, the use of specialty materials for the stress-compensating substrate increases production costs.

According to another solution to limit stress, such as described in document US20140048934, a method of controlling the flow of glue by creating a surface roughness of the substrate on which is welded a component has been provided.

This method inhibits the glue flow and enables to form balanced glue beads, thus decreasing high stress concentrations on the chip. These glues beads are also referred to as “fillet”.

However, the creation of surface roughnesses has a limited impact on the risk of cleavage, in particular for thick components, typically with a thickness greater than 200 micrometers.

Document U.S. Pat. No. 6,940,182 also provides a method of managing glue between an integrated chip and a substrate so as to decrease mechanical stress and improve the reliability of the hybridized component. This document provides the use of a dam around the chip to control the shape and the accumulation of the glue so as to decrease the stress resulting from edge effects. The dam enables to control the wetting angle of the glue to provide a much smaller stress component along the direction perpendicular to the surface of the underlying substrate, by decreasing the glue bead thus formed.

However, the use of a dam also has a limited impact on the risk of cleavage, in particular for components having a thickness that can vary between a few tens and a few hundreds of micrometers.

Document U.S. Pat. No. 7,301,222 describes another method to control the glue beads on deposition of the glue between an integrated chip and a substrate by using grooves. Again, this solution has a limited impact on the risk of cleavage, in particular for components having a thickness that can vary between a few tens and a few hundreds of micrometers.

The technical problem to be solved actually lies in the manufacturing of a hybridized component having a limited risk of cleavage, in particular when the hybridized component is used at extreme temperatures, with the possibility of using a thickness of the detection circuit between a few tens and a few hundreds of micrometers.

### SUMMARY OF THE DISCLOSURE

To address this technical problem, the invention provides preparing the detection circuit with a sacrificial layer before it is attached to the readout circuit. Thus, the sacrificial layer extends at least on the edges of the detection circuit and the glue deposition can be carried out conventionally. After the deposition of the glue, the latter thus extends on the sacrificial layer formed on the edges of the detection circuit, so that the removal of this sacrificial layer causes the forming of trenches.

According to a first aspect, the invention thus concerns a method of manufacturing a hybridized component comprising the following steps:
attaching of a detection circuit to a readout circuit; and
application of glue between the detection circuit and the readout circuit.

The invention is characterized in that the method also comprises the following steps:
deposition of a sacrificial layer on the detection circuit before the step of attaching of the detection circuit to the readout circuit so that the sacrificial layer extends at least on the edges of the detection circuit; and
removal of the sacrificial layer after the step of application of the glue between the detection circuit and the readout circuit so as to form trenches around said detection circuit.

Although the conventional solution to limit cleavage advocates the control of the glue deposition, the invention provides an alternative solution in which the method of glue deposition is not constrained. Indeed, the invention implements a sacrificial layer to predetermine the thickness and the shape of the trenches around the detection circuit.

Conversely to solutions of the state of the art, the invention is particularly efficient for thick detection circuits, typically with a thickness greater than 200 micrometers.

Further, before the step of removal of the sacrificial layer, it is possible to perform a thinning of the glue and of the detection circuit. This step is often used when the detection circuit is hybridized by transfer, using a substrate having the detection circuit formed thereon.

Once hybridized on the readout circuit, this substrate is no longer necessary and sometimes disturbing from an electrooptical viewpoint. It is thus removed by mechanical or chemical thinning.

To obtain a trench with a dimension sufficient to limit the risk of cleavage, the deposition of a sacrificial layer is preferably performed with a thickness of at least 1 micrometer. More preferably still, the deposition of a sacrificial layer is performed with a thickness of at least 1.5 micrometers.

Further, to protect the connections, the step of deposition of the sacrificial layer on the detection circuit may be carried out by sputtering, coating, evaporation, or any other method of deposition of a sacrificial layer while protecting the surface of the detection circuit intended to be attached to the readout circuit. As concerns the method of deposition of the sacrificial layer, it is thus possible to use any method enabling to deposit a sacrificial layer at least on the edges of the detection circuit, without affecting its active surface. This active surface corresponds to the surface of the detection circuit intended for the hybridizing with the readout circuit.

Further, it is also possible to apply a temporary protection resin or adhesive on this active surface, before the step of deposition of the sacrificial layer. For this purpose, the temporary resin or adhesive needs to be deposited without extending over the edges of the detection circuit. As a variant, it is also possible to place the detection circuit on a support protecting the active surface during the deposition of the sacrificial layer.

Further, it is possible to deposit or not the sacrificial layer on the back side of the detection circuit, that is, the surface opposite to the active surface. Indeed, before the step of removal of the sacrificial layer, it is preferable to perform a thinning of the glue and of the detection circuit. Now, this thinning step causes the removal of the sacrificial layer deposited on the back side.

As concerns the removal of this layer, it may be carried out by chemical etching or dissolution. For example, the sacrificial layer may be made of zinc sulfide and the step of removal of the sacrificial layer is carried out with hydrochloric acid. The hydrochloric acid enables to remove the zinc sulfide without etching an epoxy glue or the detection circuit, which could be made of gallium antimonide or of cadmium-zinc telluride.

Of course, other materials may be used by the sacrificial layer and the step of removal of the sacrificial layer, according to the materials forming the glue and the detection circuit.

Preferably, to remove any trace of a chemical treatment, the method also comprises a step of rinsing of the hybridized component carried out after the step of removal of the sacrificial layer.

According to a second aspect, the invention concerns a hybridized component comprising:
a readout circuit;
a detection circuit attached to the readout circuit via connections, the detection circuit having a thickness capable of varying between a few tens and a few hundreds of micrometers;
glue extending between the readout circuit and the detection circuit and around the connections; et
trenches formed around the edges of the detection circuit and along the entire height of the detection circuit by means of the manufacturing method according to the first aspect of the invention.

### BRIEF DESCRIPTION OF THE DRAWINGS

The way in which the invention can be carried out and the advantages resulting therefrom will better appear from the following non-limiting example of embodiment, given as an indication, in relation with the accompanying drawings.

FIG. 1 is a flowchart of the steps of a method of manufacturing a hybridized component according to an embodiment of the invention;

FIG. 2 is a simplified representation in cross-section of a first manufacturing step of the method of FIG. 1;

FIG. 3 is a simplified representation in cross-section of a second manufacturing step of the method of FIG. 1;

FIG. 4 is a simplified representation in cross-section of a third manufacturing step of the method of FIG. 1;

FIG. 5 is a simplified representation in cross-section of a fourth manufacturing step of the method of FIG. 1; and

FIG. 6 is a simplified representation in cross-section of a fifth manufacturing step of the method of FIG. 1.

### DETAILED DESCRIPTION

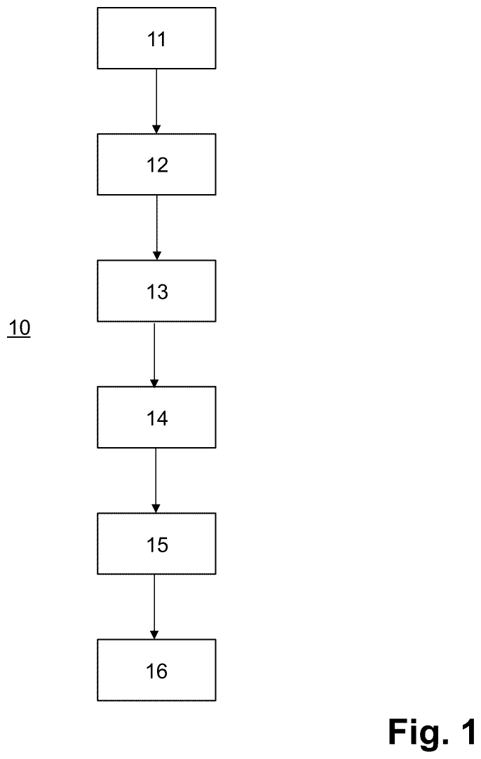

FIG. 1 illustrates a method of manufacturing 10 a hybridized component 20, comprising a readout circuit 22 and a detection circuit 21.

According to the invention, the manufacturing method comprises a first step 11 of deposition of a sacrificial layer 23 on detection circuit 21. In this step 11, sacrificial layer 23 may be deposited by all known methods of deposition of a sacrificial layer, and in particular by sputtering, coating, evaporation, or any other method of deposition of a sacrificial layer.

Preferably, on deposition of this sacrificial layer 23, the surface of detection circuit 21 intended to be attached to readout circuit 22 is protected. Further, the step of deposition 11 of sacrificial layer 23 is preferably carried out by controlling the thickness of the sacrificial layer 23, typically to obtain a thickness of at least 1 micrometer and preferably of at least 1.5 micrometers. For example, a 2-micrometer thickness can thus be searched for. As concerns the material forming this sacrificial layer 23, it may be made of zinc sulfide or of any other material adapted to being removed by chemical etching or dissolution.

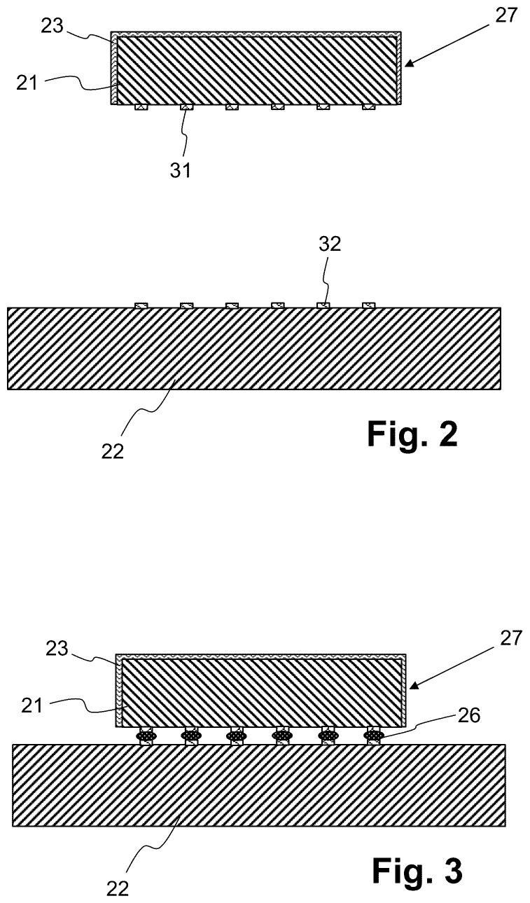

After this step 11 of deposition of the sacrificial layer, as illustrated in FIG. 2, the connectors 31 of detection circuit 21 are placed opposite the connectors 32 of readout circuit 22.

In the second step 12, detection circuit 21 is attached to readout circuit 22 by applying a soldering between these connectors 31 and 32, thus forming a connection 26, as illustrated in FIG. 3.

Glue 24 is then applied, during step 13, between detection circuit 21 and readout circuit 22.

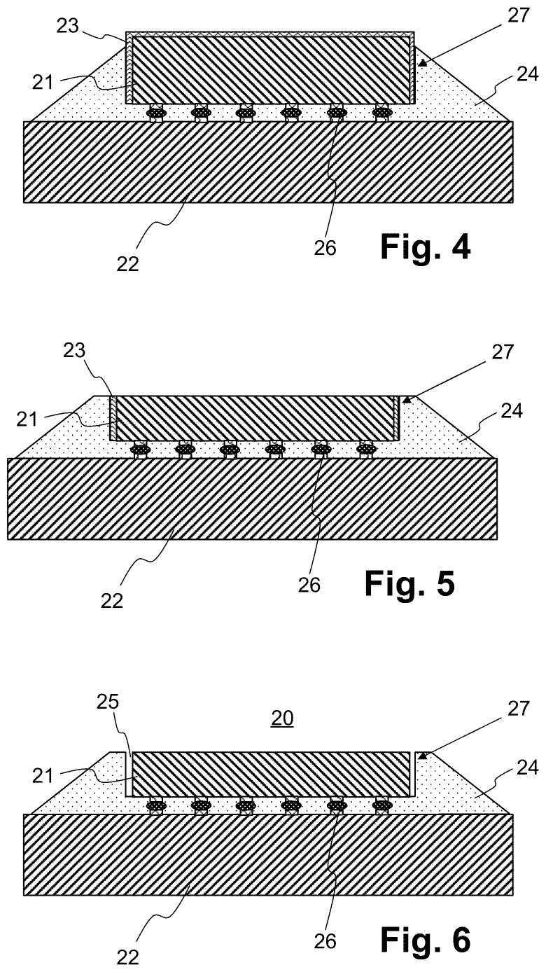

As illustrated in FIG. 4, this glue 24 extends between connections 26 but also on the edges 27 of detection circuit 21.

Then, it is possible to provide a step 14 of thinning of detection circuit 21, which also causes a removal of an upper part of glue 24 and of sacrificial layer 23, as illustrated in FIG. 5.

During a step 15, sacrificial layer 23 is removed, preferably by chemical etching or dissolution. When sacrificial layer 23 is made of zinc sulfide, a chemical etching may be carried out by means of hydrochloric acid.

At the end of this step of removal of sacrificial layer 23, trenches 25 are formed on the edges of detection circuit 21.

Further, it is also possible to implement a last step, in the case in point of rinsing 16 of the hybrid component 20 formed by these different steps, so as to limit possible residues of hydrochloric acid or of any other etch material used.

As illustrated in FIG. 6, the invention thus enables to obtain a hybridized component 20 with trenches 25 formed on the edges 27 of detection circuit 21.

The invention enables to simply form these trenches 25, even with a detection circuit 21 having a thickness that can between a few tens and a few hundreds of micrometers.

The invention enables to obtain a hybridized component 20 with a limited risk of cleavage since glue 24 no longer extends in contact with the edges 27 of detection circuit 21.

1. A method of manufacturing a hybridized component comprising the following steps:
attaching of a detection circuit to a readout circuit; and
application of glue between the detection circuit and the readout circuit;
wherein the method also comprises the following steps:
deposition of a sacrificial layer on the detection circuit before the step of attaching of the detection circuit to the readout circuit, so that the sacrificial layer extends at least over edges of the detection circuit; and
removal of the sacrificial layer after the step of application of the glue between the detection circuit and the readout circuit so as to form trenches around said detection circuit.

2. The method of manufacturing a hybridized component according to claim 1, wherein, before the step of removal of the sacrificial layer, the method also comprises a step of thinning of the glue and of the detection circuit.

3. The method of manufacturing a hybridized component according to claim 1, wherein the thickness of the sacrificial layer deposited on the detection circuit is at least 1 micrometer.

4. The method of manufacturing a hybridized component according to claim 3, wherein the thickness of the sacrificial layer deposited on the detection circuit is at least 1.5 micrometers.

5. The method of manufacturing a hybridized component according to claim 1, wherein the step of deposition of the sacrificial layer on the detection circuit is carried out by sputtering, coating, evaporation, or any other method of deposition of a sacrificial layer while protecting the surface of the detection circuit intended to be attached to the readout circuit.

6. The method of manufacturing a hybridized component according to claim 1, wherein the step of removal of the sacrificial layer is carried out by chemical etching or dissolution.

7. The method of manufacturing a hybridized component according to claim 6, wherein the sacrificial layer is made of zinc sulfide and the step of removal of the sacrificial layer is carried out with hydrochloric acid.

8. The method of manufacturing a hybridized component according to claim 7, wherein the method also comprises a step of rinsing of the hybridized component carried out after the step of removal of the sacrificial layer.

9. A hybridized component comprising:
a readout circuit;
a detection circuit connected to the readout circuit via connections, the detection circuit having a thickness capable of varying between a few tens and a few hundreds of micrometers;
glue extending between the readout circuit and the detection circuit and around the connections; and
trenches formed around the edges of the detection circuit and along the entire height of the detection circuit by means of the manufacturing method according to claim 1.
